(19) United States
(12) Patent Application Publication
(10) Pub. No.: US 2006/0249482 A1
(43) Pub. Date: Nov. 9, 2006

(54) Chemical mechanical polishing compositions for step-ll copper line and other associated materials and method of using same

(76) Inventors: Peter Wrschka, Danbury, CT (US); David Bernhard, Newtown, CT (US); Karl Boggs, Hopewell Junction, NY (US); Michael Darsillo, Woodbury, CT (US)

Correspondence Address: MOORE & VAN ALLEN PLLC, P.O. BOX 13706, Research Triangle Park, NC, 27709, US

(21) Appl. No.: 10/556,265

(22) PCT Filed: May 10, 2004
(86) PCT No.: PCT/US04/14638

§ 371 Date: Dec. 27, 2005

Related U.S. Application Data
(60) Provisional application No. 60/469,683, filed on May 12, 2003.

(51) Int. Cl. C09K 13/00; H01L 21/461; B44C 1/22

(52) U.S. Cl. 216/88; 216/89; 252/79.1; 252/79.2; 438/692

(57) ABSTRACT

A CMP composition and process for planarization of a semiconductor wafer surface having a copper barrier layer portion, said composition comprising an oxidizing agent, a boric acid component, and an abrasive.

### FIELD OF THE INVENTION

The present invention relates to a chemical mechanical polishing slurry for surfaces of a semiconductor wafer, and more particularly, to a chemical mechanical polishing slurry and a method for using the slurry to remove and polish copper, barrier materials and dielectric materials layered on semiconductor wafer surfaces.

### DESCRIPTION OF THE RELATED ART

Semiconductor wafers are used to form integrated circuits. The semiconductor wafer includes a substrate, such as silicon, into which regions are patterned for deposition of different materials having insulative, conductive or semi-conductive properties.

In order to obtain the correct patterning, excess material used in forming the layers on the substrate must be removed. Further, to fabricate functional and reliable circuitry, it is important to have a flat or planar semiconductor wafer surface. Thus, it is necessary to remove and/or polish certain surfaces of a semiconductor wafer.

Chemical Mechanical Polishing or Planarization (“CMP”) is a process in which material is removed from a surface of a semiconductor wafer, and the surface is polished (planarized) by coupling a physical process such as abrasion with a chemical process such as oxidation or chelation. In its most rudimentary form, CMP involves applying slurry, a solution of an abrasive and an active chemistry, to a polishing pad that buffs the surface of a semiconductor wafer to achieve the removal, planarization, and polishing process. It is not desirable for the removal or polishing process to be comprised of purely physical or purely chemical action, but rather the synergistic combination of both in order to achieve fast uniform removal. In the fabrication of integrated circuits, the CMP slurry should also be able to preferentially remove films that comprise complex layers of metals and other materials so that highly planar surfaces can be produced for subsequent photolithography, or patterning, etching and thin-film processing.

Recently, copper has been used for metal interconnects in integrated circuits. FIG. 1 shows an illustration a copper damascene processing step in a semiconductor fabrication step. The layers that must be removed and planarized include copper layer 12, (about 1-1.5 μm thick) on top of a thin copper seed layer 14, (about 0.05-0.15 μm thick). These copper layers are separated from the dielectric material surface by a layer of barrier material 18, (about 50-300 Å thick) which prevents diffusion of copper into the oxide dielectric material 16. The key to obtaining good uniformity across the wafer surface after polishing is by using a slurry that has the correct removal selectivities for each material. If appropriate material removal selectivity is not maintained, unwanted dishing of copper and/or erosion of the dielectric material may occur.

Dishing occurs when too much copper is removed such that the copper surface of a feature is recessed relative to the dielectric surface of the semiconductor wafer. Dishing primarily occurs when the copper and copper-barrier (also referred to as copper-liner) material removal rates are disparate. Oxide erosion occurs when the dielectric material removal rate is locally much higher than the surrounding field material. Dishing and oxide erosion are dependent on area, wafer pattern and pitch.

Due to the difference in chemical reactivity between copper and barrier liner materials, two chemically distinct slurries are often used in the copper CMP process. The first step slurry (Step-I) is typically used to rapidly planarize the topography and to uniformly remove the excess copper, with the polish stopping at the barrier layer. The second step slurry (Step-II) typically removes the copper-liner material at a high removal rate and stops on the dielectric layer, or alternatively on a cap layer that has been applied to protect the oxide.

U.S. patent application Ser. No. 10/315,641 for “Passivative Chemical Mechanical Polishing Composition for Copper Film Planarization” and “Improved Chemical Mechanical Polishing Compositions for Copper and Associated Materials and Method Using Same” concurrently filed herewith and both incorporated herein by reference in their respective entireties, teach novel Step-1, planarization compositions useful for removing and planarizing copper surfaces.

One object of this invention therefore is to provide a Step-II, CMP composition, for barrier or liner removal and planarization of a wafer surface after a Step-I polishing step of a CMP process for removal of copper overburden.

It is a further object of the present invention to provide a Step-II, CMP composition, for barrier or liner removal and planarization of a wafer surface after a Step-I polishing step of a CMP process, which uses the copper removal compositions disclosed in the U.S. patent applications identified hereinabove.

A further object of the present invention is to provide a Step-II copper CMP slurry, which enables a high removal rate of barrier material, while minimizing unwanted dishing of copper and/or erosion of dielectric material.

A further object of this invention is to provide a Step-II CMP slurry having appropriate materials selectivity so as to minimize copper dishing and oxide erosion in a semiconductor wafer surface, thereby providing a viable CMP approach to advanced device manufacturing.

These and other objects and advantages of the invention will be apparent to those skilled in the art upon reading the following detailed description and upon reference to the drawings.

### SUMMARY OF THE INVENTION

The present invention relates to a CMP slurry composition and process designed to planarize barrier materials such as tungsten nitride, tantalum, tantalum nitride, silicon doped tantalum nitride, titanium nitride and silicon doped titanium nitride, which are associated with a copper CMP process step. And as broadly disclosed herein, the CMP slurry composition, when used in a copper damascene planarization step, reduces the occurrence of copper dishing and dielectric or oxide erosion while controlling the rates at which both dielectric and barrier materials are removed.

In one aspect, the invention relates to a CMP composition for planarization of a wafer surface having a copper barrier layer portion, in which the CMP composition includes an oxidizing agent, a boric acid component, and an abrasive.

In a further aspect, the invention relates to a method of planarizing a wafer surface having a copper-barrier, liner portion, a copper portion, and a dielectric portion, said method comprising contacting the wafer surface, under CMP conditions, with a composition having a high removal rate on copper-barrier, liner, and a removal rate on the dielectric portion that is based on the concentration of a boric acid component in the CMP composition.

Other aspects, features and embodiments of the invention will be more fully apparent from the ensuing disclosure and appended claims.

### BRIEF DESCRIPTION OF THE DRAWINGS

FIG. 1 shows an illustration of a copper damascene processing step-in a semiconductor fabrication step.

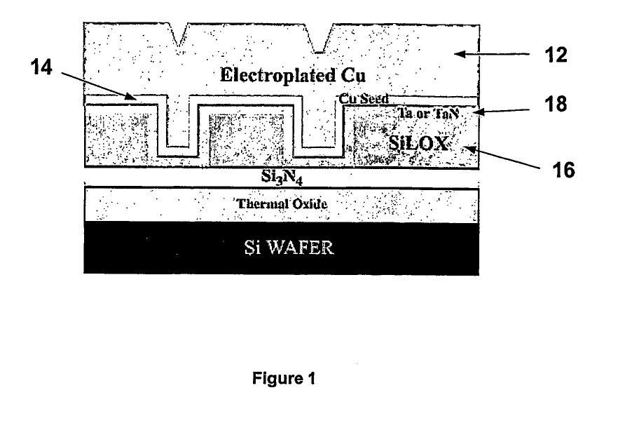

FIGS. 2(a)-2(d) show a two-step CMP process for planarizing a wafer surface after a copper damascene processing step.

FIG. 3 shows a plot of zeta potential and conductivity with respect to pH for a silica abrasive according to one embodiment of the present invention.

FIG. 4 shows a graph plotting the step height reduction from the dielectric field area into the copper line array according to a further embodiment of the present invention.

FIG. 5 shows a plot of removal rates for Ta (liner material) and SiO₂ (dielectric material) from a wafer surface according to a further embodiment of the present invention.

### DETAILED DESCRIPTION OF THE INVENTION, AND PREFERRED EMBODIMENTS THEREOF

In CMP slurries it is advantageous to independently control the relative polishing rates between the different materials of the pattern to be polished. For example, in copper polishing one will actually polish copper, liner/barrier materials such as Ta, TaN, Ti, TiN, TiW, WN and silicon doped nitrides as well as dielectrics such as SiO₂, TEOS, PSG, BPSG, or any low-K dielectric.

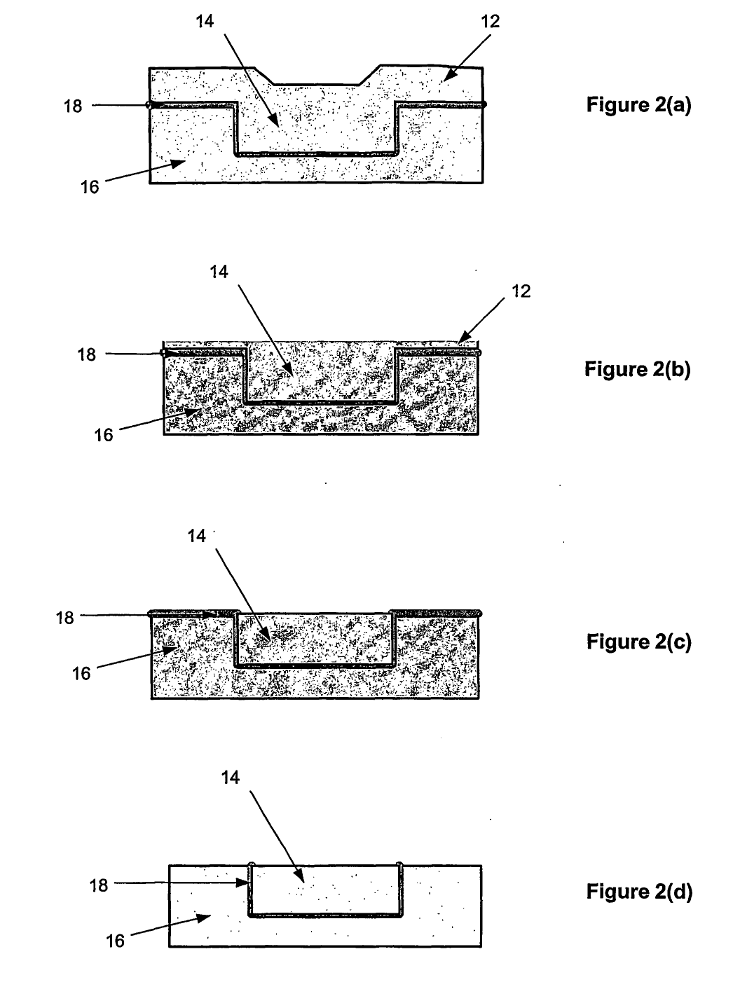

FIG. 2(a) shows an illustration of a copper filled feature after a copper damascene processing step where copper 12, fills feature 14, previously etched into dielectric material 16, by a damascene processing step. A barrier liner 18 deposited prior to copper fill, prevents diffusion of copper into dielectric material 16. In a first CMP process step, often referred to as Step 1, the bulk of the copper topography will be planarized to at or just above the barrier liner as shown in FIG. 2(b). In some cases, the planarization Step-I will proceed until exposure of the barrier liner, and the Step 1 formulation having a high selectivity for copper, will cause the copper material to dish slightly below the topography of barrier liner 18, as shown in FIG. 2(c). In a final planarization step, commonly referred to as a Step II process, the barrier liner 18, must be removed and planarized such that the dielectric, barrier and copper lie within the same plane, as shown in FIG. 2(d). To accomplish the Step-II process, a second CMP processing step employing a CMP composition different from that of Step I, is used. Typically, the Step II process removes the barrier liner 18, and often a thin layer (e.g. 300 Å) of the dielectric material 16. The composition used in the Step II, CMP processing step, is the subject of the present invention.

The present invention provides a novel composition useful for removing and planarizing the materials associated with a Step II, CMP process. More specifically, the present invention provides a novel composition useful in the planarization of a wafer surface having copper, liner and dielectric components therein. The novel composition comprises a boric acid component, the concentration of which, advantageously affects the removal rate and thus the selectivity of the dielectric material

The invention is based on the discovery that addition, to a CMP composition, of boric acid and/or a derivative thereof, results in a stable slurry formulation having tunable selectivity to dielectric materials. Advantageously, the removal rate of the dielectric material can be tuned or controlled by adjusting the concentration of the boric acid component(s) in the CMP composition.

Accordingly, in one embodiment, the present invention relates to a Step II, CMP composition for use in planarizing the topography of a wafer surface after a copper damascene, Step I, CMP polishing step. The composition, comprising an abrasive, and a boric acid component and optionally an oxidizing agent, is useful for leveling the wafer's topography, which may comprise any one of copper, liner and dielectric materials. The boric acid component in the CMP composition serves to passivate the dielectric material during a CMP, Step II process.

As used herein, the term “boric acid component” is intended to include boric acid, its salts and derivatives, including but not limited to: alkyl substituted borates such as, ammonium tetraphenylborate (C₆H₅)₄BNH₄, phenylboric acid C₆H₅B(OH)₂, and trimethylboroxine C₃H₉B₃O₃, polyborates such as, ammonium pentaborate octahydrate (NH₄)₂B₁₀O₁₆.8H₂O, ammonium tetraborate tetrahydrate (NH₄)₂B₄O₇.4H₂O, and potassium tetraborate tetrahydrate K₂B₄O₇.4H₂O, fluoride substituted borates such as, fluoroboric acid HBF₄, ammonium and tetrafluroborate NH₄BF₄, esters of boric acid such as, trimethylborate (CH₃O)₃B, and triethylborate (C₂H₅O)₃B, and oxidation and dehydration products of boric acid such as, boron monoxide (BO)ₓ, boric anhydride B₂O₃, potassium metaborate KBO₂, and sodium perborate NaBO₃.

As will become apparent from the discussion that follows, the stable Step II, slurry composition and corresponding process provide for removal of material and polishing of semiconductor wafer surfaces with significantly no dishing or oxide erosion, with significantly no surface defects and good planarization efficiency. Further, the copper surface produced by such a Step II process has minimal corrosion tendency.

The present invention provides a novel CMP composition, which when used in a Step II, CMP process, provides for high removal rates of liner layer material, and planarization of a wafer surface comprising copper, liner and dielectric materials.

In a further embodiment, the present invention relates to a Step II, CMP composition for use in planarizing the topography of a wafer surface after a copper damascene, Step I, CMP polishing step, said composition comprising abrasive, oxidizing agent, and boric acid component in the following composition ranges by weight, based on the total weight of the composition:

| | | |
|---|---|---|
| abrasive | 0-30 | wt. %; |
| oxidizing agent | 0-30 | wt. %; and |
| boric acid component | 0.01-20 | wt. % |

said composition having tunable selectivity for liner and dielectric materials based on the concentration of the oxidizing agent and boric acid component respectively.

The CMP composition comprising abrasive, oxidizing agent and boric acid component, provides for tunable selectivity and removal rates for both dielectric and liner materials as disclosed hereinabove. Addition of corrosion inhibitor to the composition provides means by which to control removal rate and selectivity of copper in the lines, vias and trenches. As the removal rates and selectivities of the dielectric and barrier are controllable by varying the concentration of the boric acid component, and oxidizing agent respectively, the copper material removal rate and selectivity is tunable through varying the concentration of the corrosion inhibitor. Hence, the present invention advantageously relates to a CMP composition having copper, barrier and dielectric tunability.

The present invention, in a further embodiment, relates to a Step II, CMP composition for use in a Step II, CMP process, said composition comprising abrasive, oxidizing agent, corrosion inhibitor and boric acid component. Such a composition allows for the independent modification of removal rates of copper, liner and dielectric component, without affecting the removal rate of any other component. By such modification, the present invention provides for process control of the selectivity of the copper, liner and dielectric materials.

The CMP composition comprising abrasive, oxidizing agent, corrosion inhibitor and boric acid component, provides for tunable selectivity and removal rates for copper, liner and dielectric materials. The removal rate and selectivity of the dielectric material are controllable by varying the concentration of the boric acid component. The liner material removal rate and selectivity are tunable through varying the concentration of the boric acid component and/or oxidizing agent and the copper material removal rate is tunable by varying the concentration of the oxidizing agent and/or passivating agent Hence, the present invention broadly relates to a CMP composition having copper, liner and dielectric selectivity and tunability.

The CMP composition of the invention in a preferred embodiment is an aqueous slurry composition, comprising abrasive, oxidizing agent, corrosion inhibitor and boric acid component in the following composition ranges by weight, based on the total weight of the composition:

| | | |
|---|---|---|
| abrasive | 0-30 | wt. %; |
| oxidizing agent | 0-30 | wt. %; |
| boric acid component | 0.01-20 | wt. % and |
| corrosion inhibitor | 0-10 | wt. % |

In a more preferred embodiment, the composition of the invention comprises a silica abrasive, hydrogen peroxide (H₂O₂) as oxidizing agent, and benzotriazole (BTA) as corrosion inhibitor, in the following composition ranges by weight, based on the total weight of the composition:

| | | |
|---|---|---|
| silica abrasive | 0-30 | wt. %; |
| H₂O₂ | 1-30 | wt. %; |
| BTA | 0.01-10 | wt. %; and |
| boric acid | 0.1-5 | wt. % |

In a still more preferred embodiment, the CMP composition comprises the following components by weight, based on the total weight of the composition:

| | | |
|---|---|---|
| silica abrasive | about 13 | wt. %; |
| H₂O₂ | about 5 | wt. %; |
| BTA | about 0.4 | wt. %; |
| boric acid | about 2.0 | wt. % |
| water | about 79.6 | wt. % and |

| | |
|---|---|
| KOH | negligible. |

with the total wt. % of all components in the composition totaling to 100 wt. %. KOH is used as base in the above composition to adjust the pH of the CMP composition to about 6.0.

Table 1 shows a comparison of removal rates for a Ta liner material and a SiO₂ dielectric material, where the second composition shown in Row 2 includes approximately 1 wt % boric acid. Advantageously, the addition of boric acid and/or derivatives thereof, provides means by which to tune the selectivity and removal rate of the barrier material (Ta) to the dielectric material (SiO₂).

TABLE 1
Comparison of Step-II Copper Polishing Composition Having 1 wt % Boric acid.

| | | | | | | Removal Rate in | | |
|---|---|---|---|---|---|---|---|---|
| | | | | | | Å/min | | |
| Silica | H₂O₂ | Buffer | Boric acid | | BTA | (WIWNU in %) | | |
| (wt. %) | (wt. %) | (wt. %) | (wt. %) | pH | (wt. %) | Ta | SiO₂ | Other |
| 13 | 5 | ˜2 | 0 | 6 | 0.1 | 1354 | 1036 | Buffer |
| | | | | | | 1253 | | Phosphoric |
| | | | | | | | | (85%) + KOH |
| | | | | | | | | (45%) |
| 13 | 5 | ˜2 | 1 | 6 | 0.1 | 1331 | 504 | Buffer as above |

Table 1 evidences the advantage of boric acid addition to a CMP composition for Step II removal of liner material in a copper-planarization step, where a 1% addition of boric acid reduces the dielectric removal rate by half.

TABLE 2
Comparison of Step II, Copper-liner Removal Rates by varying
the concentration of oxidizing agent. (CMP conditions 3
psi downforce, 90 rpm table and quill velocity.)

| | | | | | Ta Removal |
|---|---|---|---|---|---|
| Silica | H₂O₂ | Boric acid | | BTA | Rate in Å/min |
| (wt. %) | (wt. %) | (wt. %) | pH | (wt. %) | (WIWNU in %) |
| 13 | 1 | 1 | 6 | 0.1 | 264 |
| 13 | 10 | 1 | 6 | 0.1 | 608 |

Table 2 shows a comparison of removal rates for a Ta liner material as a function of oxidizing agent (H₂O₂) concentration. The liner removal rate of the CMP composition of the present invention may be independently controlled by varying the concentration of the oxidizing agent as the oxidizing agent serves to oxidize the barrier material in the barrier-polishing step.

The abrasive component as used herein may be of any suitable type, including, without limitation, oxides, metal oxides, silicon nitrides, carbides, etc. Specific examples include silica, alumina, silicon carbide, silicon nitride, iron oxide, ceria, zirconium oxide, tin oxide, titanium dioxide, and mixtures of two or more of such components in suitable form, such as grains, granules, particles, or other divided form. Alternatively, the abrasive can include composite particles formed of two or more materials, e.g., NYACOL® alumina-coated colloidal silica (Nyacol Nano Technologies, Inc., Ashland, Mass.). Alumina is a preferred inorganic abrasive and can be employed in the form of boehmite or transitional δ, ε or γ phase alumina. Organic polymer particles, e.g., including thermoset and/or thermoplastic resin(s), can be utilized as abrasives. Useful resins in the broad practice of the present invention include epoxies, urethanes, polyesters, polyamides, polycarbonates, polyolefins, polyvinylchloride, polystyrenes, polyolefins, and (meth)acrylics. Mixtures of two or more organic polymer particles can be used as the abrasive medium, as well as particles comprising both inorganic and organic components. In a preferred embodiment, the abrasive component of the present invention includes silica More preferably, the silica abrasive is of a colloidal or mono-disperse type, available commercially under a brand name such as LEVASIL® 100CK/30%-TaHS₃ procuded by H.C. Starck GmbH, Leverkusen, Geb. G8, Germany.

The pH of the present CMP compositions may be at any suitable value that is efficacious for the specific polishing operation employed. In one embodiment, the pH of the CMP composition can be in a range of from about 2 to about 11, more preferably in a range of from about 2 to about 7.0, and most preferably in a range of from about 3 to about 6.

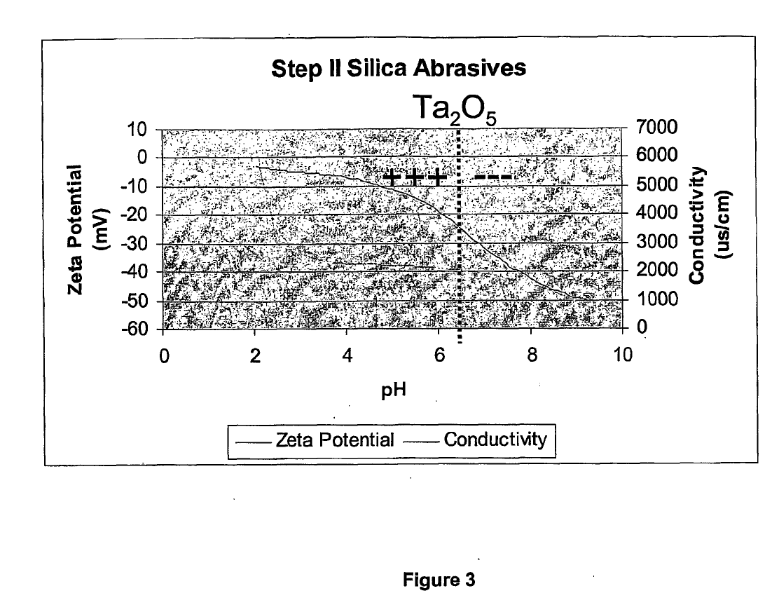

FIG. 3 shows a plot of zeta potential and conductivity with respect to pH for a silica mono-disperse abrasive having an approximate mean particle size of 65 mm and a spherical morphology. The zeta potential of a particle defines the electrostatic charge on that particle in a particular liquid. In the case of the present invention, as solution pH increases, silica abrasive zeta potential decreases.

Moreover, FIG. 3 further identifies Ta₂O₅ (by-product from oxidation of Ta barrier material with oxidizing agent) as having a positive zeta potential at pHs below around 6.5. The silica particle having a negative zeta potential of around −30 mV at a pH of around 6.0, will electrostatically attract the Ta₂O₅ wafer surface having a positive zeta potential. And advantageously, the slurry composition of the present invention having a pH of around 6.0, will provide optimal conditions for the dissolution of the oxidized tantalum.

The term oxidizing agent as used herein is defined as any substance which removes metal electrons and raises the atomic valence and includes but is not limited to hydrogen peroxide (H₂O₂), ferric nitrate (Fe(NO₃)₃), potassium iodate (KIO₃), potassium permanganate (KMnO₄), nitric acid (HNO₃), ammonium chlorite (NH₄ClO₂), ammonium chlorate (NH₄ClO₃), ammonium iodate (NH₄IO₃), ammonium perborate H₄BO₃), ammonium perchlorate H₄ClO₄), ammonium periodate (NH₄IO₃), ammonium persulfate (NH₄)₂S₂O₈), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), urea hydrogen peroxide ((CO(NH₂)₂)H₂O₂). The preferred oxidizing agent for the CMP slurry composition of the instant invention is hydrogen peroxide.

Alternatively, the oxidizing agent may comprise an amine-N-oxide having the formula (R¹R²R³N→O), wherein R¹R²R³ are independently selected from the group consisting of: H, aryl, and C₁-C₈ alkyl. Specific examples of amine-N-oxides include but are not limited to 4-methyhmorpholine N-oxide (C₅H₁₁NO₂) and pyridine-N-oxide (C₅H₅NO).

The term corrosion inhibitor as used herein, is intended to mean any substance that reacts with copper and/or oxidized copper thin film to passivate the copper layer and prevent excessive etching of the copper surface during CMP. Preferably, the CMP composition of the present invention has a static metal etch rate of less than 500 Å, more preferably less than 200 Å, and most preferably less than 50 Å.

The corrosion inhibitor component in the CMP composition of the invention may comprise one or more inhibitor components including for example, imidazole, aminotetrazole, benzotriazole, benzimidazole, amino, imino, carboxy, mercapto, nitro, alkyl, urea and thiourea compounds and derivatives, etc. Dicarboxylic acids such as glycine, oxalic acid, malonic acid, succinic acid, nitrilotriacetic acid, iminodiacetic acids, and combinations thereof are also useful corrosion inhibitors. Preferred inhibitors include tetrazoles and their derivatives. In a specific embodiment, the corrosion inhibitor is 5-aminotetrazole (ATA) or benzotriazole (BTA).

The solvents employed in the CMP composition of the invention can be single component solvents or multicomponent solvents, depending on the specific application. In one embodiment of the invention, the solvent in the CMP composition is water. In another embodiment, the solvent comprises an organic solvent, e.g., methanol, ethanol, propanol, butanol, ethylene glycol, propylene glycol, glycerin, etc. In yet another embodiment, the solvent comprises a water-alcohol solution. A wide variety of solvent types and specific solvent media can be employed in the general practice of the invention to provide a solvating/suspending medium in which the abrasive is dispersed and in which the other components are incorporated to provide a composition of appropriate character, e.g., of slurry form, for application to the platen of the CMP unit to provide a desired level of polishing of the copper on the wafer substrate.

Bases can be optionally employed for pH adjustment in compositions of the invention. Illustrative bases include, by way of example, potassium hydroxide, ammonium hydroxide, tetramethylammonium hydroxide (TMAH), tetraethylammonium hydroxide, trimethyl hydroxyethylammonium hydroxide, methyl tri(hydroxyethyl)ammonium hydroxide, tetra(hydroxyethyl)ammonium hydroxide, and benzyl trimethylammonium hydroxide.

Acids can also be optionally employed for pH adjustment and buffering in the CMP compositions of the invention. The acids used can be of any suitable type, including, by way of example, formic acid, acetic acid, propanoic acid, butanoic acid, pentanoic acid, isovaleric acid, hexanoic acid, heptanoic acid, octanoic acid, nonanoic acid, lactic acid, hydrochloric acid, nitric acid, phosphoric acid, sulfuric acid, hydrofluoric acid, malic acid, fumaric acid, malonic acid, glutaric acid, glycolic acid, salicylic acid, 1,2,3-benzenetricarboxylic acid, tartaric acid, gluconic acid, citric acid, phthalic acid, pyrocatechoic acid, pyrogallol carboxylic acid, gallic acid, tannic acid, and mixtures including two or more acids of the foregoing or other types. In a preferred embodiment, the CMP composition of the present invention includes phosphoric acid.

Chelating agents when present are intended to mean any substance that in the presence of a water containing solution solubilizes or etches the oxidized copper material. Copper chelating agents useful in the present invention include but are not limited to mineral acids (i.e. hydrochloric acid, nitric acid), inorganic acids (i.e. phosphoric acid) and organic acids and amino acids (i.e. glycine, citric acid, acetic acid and maleic acid). A preferred chelating agent is glycine.

Amines when present can be of any suitable type, including, by way of example, hydroxylamine, monoethanolamine, diethanolamine, triethanolamine, diethyleneglycolamine, N-hydroxylethylpiperazine, N-methylethanolamine, N,N-dimethylethanolamine, N-ethylethanolamine, N,N-diethylethanolamine, propanolamine, N,N-dimethylpropanolamine, N-ethylpropanolamine, N,N-diethylpropanolamine, 4-(2-hydroxyethyl)morpholine, aminoethylpiperazine, and mixtures including two or more of the foregoing or other amine species.

Surfactants when optionally employed in the CMP compositions of the invention can be of any suitable type, including non-ionic, anionic, cationic, and amphoteric surfactants, and polyelectrolytes including, for example: salts of organic acids; alkane sulfates (e.g., sodium dodecyl sulfate); alkane sulfonates; substituted amine salts (e.g., cetylpyridium bromide); betaines; polyethylene oxide; polyvinyl alcohol; polyvinyl acetate; polyacrylic acid; polyvinyl pyrrolidone; polyethyleneimine; and esters of anhydrosorbitols, such as those commercially available under the trademarks Tween® and Span®, as well as mixtures including two or more of the foregoing or other surfactant species.

The present invention in a further embodiment, provides a method for planarizing a wafer surface having a copper-barrier, liner portion, a copper portion, and a dielectric portion, said method comprising contacting the wafer surface, under CMP conditions, with a composition having a high removal rate on the copper-barrier, liner and a removal rate on the dielectric portion that is based on the concentration of a boric acid component in the CMP composition.

In a still further embodiment, the present invention provides a method for planarizing a wafer surface having a copper-barrier, liner portion, a copper portion, and a dielectric portion, said method comprising contacting the wafer surface, under CMP conditions, with a composition having a high removal rate on the copper-barrier, liner and removal rates of the copper-barrier, liner, copper and dielectric portions that are based on the concentration of at least one component in the CMP composition.

Preferably, the CMP composition of the present invention provides for selectivities of Cu:Ta:oxide of at least 1:10:10 and barrier liner removal rates of at least 300 Å/min., more preferably at least 400 Å/min. and most preferably at least 600 Å/min.

The CMP composition of the invention can be readily formulated in a so-called ‘day tank’ or ‘storage tank,’ or the CMP composition can be provided as a two-part formulation or a multi-part formulation that is mixed at the point of use. The individual parts of the multi-part formulation can be mixed at the polishing table, polishing belt or the like, or in an appropriate container shortly before reaching the polishing table.

In one embodiment, the CMP composition of the present invention is formulated as a single-package shortly before reaching the polishing table, according to the following process steps:
(a) combining de-ionized water and an acid component with an abrasive component under vigorous mixing until pH of approximately 2.5;
(b) adding boric acid component to step (a);
(c) adding corrosion inhibitor component to step (b);
(d) mixing step (c) for a period of time that is at least 1 hour;
(e) adding base or alkaline material to step (d) until pH of approximately 6.0;
(f) adding oxidizing agent to step (e); and
(g) allowing (f) to age for approximately one hour prior to use in CMP process.

In a more preferred embodiment, the CMP composition of the present invention is formulated as a single-package according to the following process steps:
(a) combining de-ionized water and nitric acid with silica abrasive under vigorous mixing until pH of approximately 2.5;
(b) adding boric acid component to step (a);
(c) adding benzotriazole to step (b);
(d) mixing step (c) for a period of time that is at least 1 hour;
(e) adding KOH to step (d) until pH of approximately 6.0;
(f) adding H₂O₂ to step (e); and
(g) allowing (f) to age for approximately one hour prior to use in CMP process.

In all such embodiments, the mixing of ingredients or parts to form the final composition occurs in an appropriate container shortly before reaching the polishing table, at the point of use, or with mixing at the polishing table, polishing belt or the like.

The CMP composition of the present invention can be utilized in a conventional manner in CMP operation, by application of the CMP composition to the wafer surface in a conventional fashion, and polishing of the surface can be carried out using a conventional polishing element such as a polishing pad, polishing belt, or the like.

Generally, the Step II, CMP copper slurry is applied to a pad contained on a polishing instrument. Polishing instrument parameters such as down force (DF), flow rate (FR), table speed (TS), quill speed (QS), and pad type can be adjusted to effect the results of the CMP slurry. These parameters are important in obtaining efficient planarization results and limiting dishing and erosion. Although these parameters may be altered, when used with the CMP slurry of the present invention, the standard conditions used are DF of 3 psi, FR of 200 ml/min, TS of 90 rpm QS of 90 rpm and the IC 1000 pad type.

The CMP composition of the invention is advantageously employed to polish barrier, metal and dielectric surfaces of semiconductor substrates, without the occurrence of dishing or other adverse planarization deficiencies in the polished wafer surface.

CMP slurry compositions of the invention are highly effective for Step-II copper polishing of semiconductor wafer substrates, e.g., polishing of patterned copper wafers. The CMP compositions of the invention can be readily prepared by mixing of ingredients in the desired single-package or multi-part formulations, consistent with the foregoing discussion herein of single-package and multi-part formulations. The concentrations of the respective ingredients can be widely varied in specific formulations of the CMP composition, in the practice of the invention, and it will be appreciated that the CMP composition of the invention can variously and alternatively comprise, consist or consist essentially of any combination of ingredients consistent with the disclosure herein.

The features and advantages of the invention are more fully shown by the empirical examples and results discussed below.

### EXAMPLE 1

Bulk copper overburden was removed from an 854 Reticle (854 CMP025) wafer manufactured by Sematech, Inc. using a Step I slurry composition for bulk copper removal. Copper lines were polished using the Step II slurry composition outlined in Row 2 of Table 1 hereinabove. Careful inspection with an optical microscope showed that all liner was removed evenly and uniformly within 30 s. To ensure that the Cu lines were electrically isolated and shorts eliminated, a thin layer of SiO₂ (200-300 Å) was removed as well.

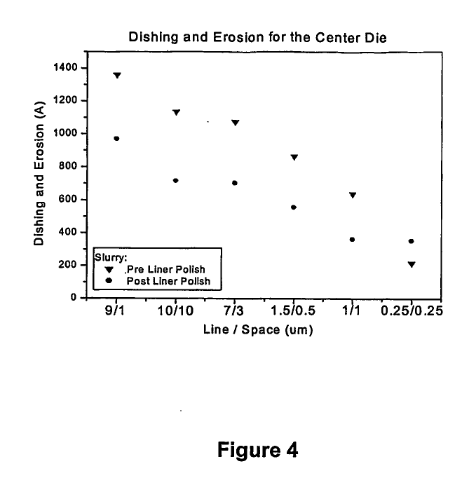

FIG. 4 shows a graph plotting the step height reduction from the dielectric field area into the copper line array pre and post liner polish with the CMP slurry composition outlined in Row 2 of Table 1. In addition to removing the Ta liner the Step II CMP composition also planarized the wafer surface. Dishing and Erosion measures the step height from the field area, unpatterned, open areas of the chip, into the copper line arrays. The step height from pre to post liner polish is reduced by up to 400 Å for line arrays with a variety of line and spacer widths.

### EXAMPLE 2

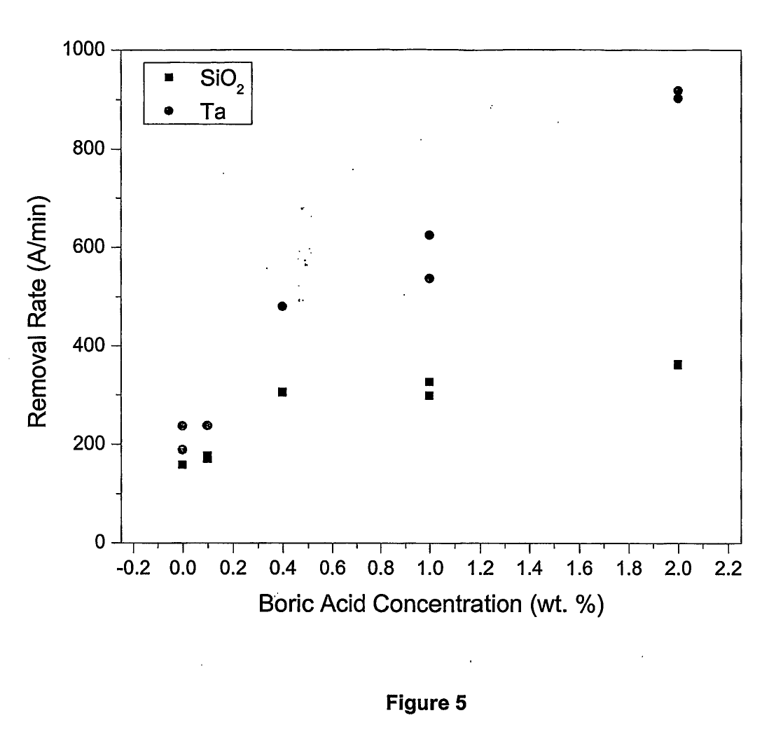

FIG. 5 shows a plot of removal rates for a thin film of Ta (liner material) and SiO₂ (dielectric material) present on a Si wafer surface as a function of weight percent concentration of boric acid component in a CMP composition. The composition comprising 13 wt. % silica, 10 wt. % hydrogen peroxide, 0.1 wt % BTA, pH 6.0 and varying wt % boric acid. At low boric acid concentrations the material removal rates as shown are fairly low, too low to insure high wafer throughput in IC chip manufacturing. Adding boric acid to the slurry increases both removal rates. However, the Ta removal rate shows a stronger increase with increasing boric acid concentration. At 0.4% wt boric acid the increase in the SiO₂ removal rate has saturated, but the Ta removal rate is still further increasing. This shows, that with the current Step 2 formulation, containing boric acid, the polishing process is highly tunable by the boric acid content. Thus depending on the specific needs of a particular integration process the Ta and SiO₂ removal rates can be adjusted accordingly.

While this invention has been disclosed and discussed primarily in terms of specific embodiments thereof, it is not intended to be limited thereto. Other modifications and embodiments will be apparent to the worker in the art.

What is claimed is:

1. A CMP composition for planarization of a wafer surface having a copper barrier layer portion, said composition comprising an oxidizing agent, a boric acid component, and an abrasive.

2. The CMP composition according to claim 1, where in said wafer surface further comprises copper and a dielectric material.

3. The CMP composition according to claim 1, wherein said barrier layer portion comprises a material selected from the group consisting of Ta, TaN, Ti, TiN, TiW, WN and silicon doped nitrides.

4. The CMP composition according to claim 2, further comprising a corrosion inhibitor.

5. The CMP composition according to claim 4, wherein said abrasive, oxidizing agent, boric acid component and corrosion inhibitor are present in the following composition ranges by weight, based on the total weight of the composition:

| | | |
|---|---|---|
| abrasive | 0.01 to 30 | wt. %; |
| oxidizing agent | 1 to 30 | wt. %; |
| corrosion inhibitor | 0.01 to 10 | wt. %; and |
| boric acid component | 0.01 to 10 | wt. %. |

6. The CMP composition according to claim 5, wherein said boric acid component passivates the dielectric material.

7. The CMP composition according to claim 1 being stable.

8. The CMP composition according to claim 1, wherein said boric acid component is selected from the group consisting of:

9. The CMP composition according to claim 1, wherein said boric acid component is boric acid.

10. The CMP composition according to claim 5 providing for tunable selectivity and removal rates for both dielectric and barrier materials.

11. The CMP composition according to claim 10, wherein the removal rate and selectivity of the dielectric are controllable by varying the concentration of the boric acid component.

12. The CMP composition according to claim 10, wherein the barrier material removal rate and selectivity are tunable through varying the concentration of the oxidizing agent.

13. The CMP composition according to claim 5, comprising the following ranges by weight, based on the total weight of the composition:

| | | |
|---|---|---|
| silica abrasive | 0 to 30 | wt. %; |
| H₂O₂ | 1 to 30 | wt. %; |
| BTA | 0.01 to 10 | wt. %; and |
| boric acid | 0.01 to 10 | wt. % |

14. The CMP composition according to claim 5, comprising the following components by weight, based on the total weight of the composition:

| | | |
|---|---|---|
| silica abrasive | about 13 | wt. %; |
| H₂O₂ | about 5 | wt. %; |
| BTA | about 0.4 | wt. %; |
| boric acid | about 2.0 | wt. % |
| water | about 79.6 | wt. % |

with the total wt. % of all components in the composition totaling to 100 wt. %.

15. The CMP composition according to claim 1, wherein said abrasive component is selected from the group consisting of: oxides, metal oxides, silicon nitrides, and carbides.

16. The CMP composition according to claim 1, wherein said abrasive component is a silica mono-disperse abrasive having an approximate mean size of 65 nm and a spherical morphology.

17. The CMP composition according to claim 1, having a pH in a range of from about 2 to about 7.

18. The CMP composition according to claim 1, wherein said oxidizing agent is selected from the group consisting of: hydrogen peroxide (H₂O₂), ferric nitrate (Fe(NO₃)₃), potassium iodate (KIO₃), potassium permanganate (KMnO₄), nitric acid (HNO₃), ammonium chlorite (NH₄ClO₂), ammonium chlorate (NH₄ClO₃), ammonium iodate (NH₄IO₃), ammonium perborate (NH₄BO₃), ammonium perchlorate (NH₄ClO₄), ammonium periodate (NH₄IO₃), ammonium persulfate ((NH₄)₂S₂O₈), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), and urea hydrogen peroxide ((CO(NH₂)₂)H₂O₂).

19. The CMP composition according to claim 1, wherein said oxidizing agent hydrogen peroxide.

20. The CMP composition according to claim 5, wherein said corrosion inhibitor is selected from the group consisting of: tetrazoles such as imidazole, aminotetrazole, benzotriazole, benzimidazole, amino, imino, carboxy, mercapto, nitro, alkyl, urea and thiourea compounds and derivatives, dicarboxylic acids such as glycine, oxalic acid, malonic acid, succinic acid, nitrilotriacetic acid, iminodiacetic acids, and combinations thereof.

21. The CMP composition according to claim 5, wherein said corrosion inhibitor is benzotriazole.

22. The CMP composition according to claim 1, further comprising a solvent.

23. The CMP composition according to claim 22, wherein said solvent is selected from the group consisting of: water organic solvent and combinations thereof.

24. The CMP composition according to claim 5, further comprising a base for pH adjustment, wherein said base is selected from the group consisting of: potassium hydroxide, ammonium hydroxide and tetramethylammonium hydroxide (TMAH), tetraethylammonium hydroxide, trimethyl hydroxyethylammonium hydroxide, methyl tri(hydroxyethyl)ammonium hydroxide, tetra(hydroxyethyl)ammonium hydroxide, and benzyl trimethylammonium hydroxide.

25. The CMP composition according to claim 24, wherein said base is KOH.

26. The CMP composition according to claim 5, further comprising an acid for pH adjustment, wherein said acid is selected from the group consisting of: formic acid, acetic acid, propanoic acid, butanoic acid, pentanoic acid, isovaleric acid, hexanoic acid, heptanoic acid, octanoic acid, nonanoic acid, lactic acid, hydrochloric acid, nitric acid, phosphoric acid, sulfuric acid, hydrofluoric acid, malic acid, fumaric acid, malonic acid, glutaric acid, glycolic acid, salicylic acid, 1,2,3-benzenetricarboxylic acid, tartaric acid, gluconic acid, citric acid, phthalic acid, pyrocatechoic acid, pyrogallol carboxylic acid, gallic acid, tannic acid, and mixtures including two or more acids of the foregoing.

27. The CMP composition according to claim 26, wherein said acid is nitric acid.

28. A method of planarizing a wafer surface having a copper barrier layer portion, said method comprising contacting the material of the copper barrier layer under CMP conditions, with a composition effective for removing and planarizing barrier layer material, wherein the CMP composition includes an oxidizing agent, a boric acid component, and an abrasive.

29. A method of synthesizing a CMP slurry composition comprising the steps of:
(a) combining de-ionized water and an acid component with an abrasive component under vigorous mixing until pH of approximately 2.5;
(b) adding boric acid component to step (a);
(c) adding corrosion inhibitor component to step (b);
(d) mixing step (c) for a period of time that is at least 1 hour and;
(e) adding base or alkaline material to step (d) until pH of approximately 6.0;
(f) adding oxidizing agent to step (e); and
(g) allowing (f) to age for approximately one hour prior to use in CMP process.
